(19) United States
(12) Patent Application Publication
(10) Pub. No.: US 2011/0027457 A1
(43) Pub. Date: Feb. 3, 2011

(54) VAPOUR DELIVERY SYSTEM

(76) Inventor: Malcolm Woodcock, Oxford (GB)

Correspondence Address: Manelli Denison & Selter;William H Bollman, 2000 M Street NW, 7th Floor, Washington, DC, 20036, US

(21) Appl. No.: 12/735,387

(22) PCT Filed: Feb. 16, 2009
(86) PCT No.: PCT/GB2009/000416

§ 371 Date: Sep. 23, 2010

(30) Foreign Application Priority Data
Feb. 14, 2008 (GB) 0802687.4

(51) Int. Cl. C23C 16/52; B05C 11/00; C23C 16/00

(52) U.S. Cl. 427/8; 118/724; 118/712; 118/708; 427/248.1; 118/723 R

(57) ABSTRACT

A delivery system (10) for delivering species (12) to a processing (chamber 14) comprises a species container (16) for containing species supplied from a source (18) of liquid species. Heating means (44) is provided for heating the liquid species. The heating means is connected by conductors (46) to a heating control unit (48) which is operable by control means (30) to control evaporation of liquid species from container (16). Flow guide means (22, 24) guide flow of evaporated species to a processing chamber.

### FIELD OF THE INVENTION

This invention relates to a delivery system and method for delivering species to a processing chamber, and to apparatus for plasma processing of a surface of an article comprising such a delivery system.

### BACKGROUND OF THE INVENTION

Delivery systems are hereto known for delivering and metering vapour from a high boiling-point liquid into a vacuum chamber, in order to carry out a chemical or physical process within the vacuum chamber. Such known systems are not well suited to the case in which the liquid is a chemically reactive monomer.

In a known bubbler system, carrier gas bubbles through the liquid, absorbing and transporting the vapour into the vacuum chamber. In a known evaporator system, a sufficiently high vapour pressure is generated (of the order of 1 Torr) to deliver the vapour via a mass flow controller into the vacuum chamber. In a vapour delivery system, liquid is heated and drawn through a fine orifice, typically assisted by a carrier gas.

Bubbler and vapour delivery systems suffer from the disadvantage that a flow of carrier gas is required, and therefore restrictions are placed on the available range of vapour/carrier composition. Evaporator systems have the drawback that the liquid must be heated to a sufficiently high temperature in order to generate a high enough pressure to enable a mass flow controller to function. This carried with it the attendant risks of instability, including the risk of polymerisation in the case that the liquid is a monomer. Also vapour delivery systems are also prone to blockage of the fine orifice, either by particulate contamination in the liquid or as a result of a tendency to polymerise, in the case that the liquid is a monomer.

### PRIOR ART

One example of an existing method for coating a polymeric layer, using a low powered pulsed laser, is described in International Patent Application WO-A1-2005/089961 (Secretary of State for Defence) which describes a method and apparatus for depositing a polymeric material onto a substrate in which a monomeric material is introduced into a plasma chamber and ignited at a power of 0.004 to 500 W/m³.

Another example of an apparatus for forming a polymer film is described in UK Patent Application GB-A-2 343 453 (NEC Corporation). The apparatus includes a vaporisation controller. However, there is no mention of how the rate of vaporisation is increased or decreased.

The present invention arose in order to overcome problems associated with prior art system.

### SUMMARY OF THE INVENTION

According to the present invention there is provided a delivery system for delivering species to a processing chamber, the system comprising: a species container for containing species supplied from a source of liquid species; heating means for heating said liquid species, said heating means being operable to control evaporation of said liquid species from said container; and flow guide means for guiding flow of evaporated species to a processing chamber, wherein said heating means includes an immersion heater.

The present invention also provides a method of delivering species to a processing chamber, the method comprising the steps of: supplying liquid species from a source of species to a container; evaporating liquid species from said container by homogenously heating said liquid species in said container; guiding flow of evaporated species to a processing chamber.

The present invention also provides apparatus for plasma processing of a surface of an article, the apparatus comprising: a processing chamber into which an article can be placed; a delivery system for delivering a species to the processing chamber for forming a plasma in said chamber; means for generating an electrical field internally of the processing chamber for forming a plasma when said species is supplied thereto so that a surface of said article can be processed; and pressure control means for selectively controlling pressure in the processing chamber; wherein said delivery system comprises: a species container for containing species supplied from a source of liquid species; heating means for heating said liquid species, said heating means being operable to control evaporation of said liquid species from said container; and flow guide means for guiding flow of evaporated species to the processing chamber.

Other preferred and/or optional features of the invention are defined in the accompanying claims.

The invention will now be described, by way of example only, with reference to the accompanying drawings, in which:—

### BRIEF DESCRIPTION OF THE DRAWINGS

FIG. 1 is a schematic representation of a delivery system for delivering species to a processing chamber;

FIG. 2 is a graph showing change in mass of liquid species in a container as shown in FIG. 1;

FIG. 3 shows two graphs of a rate of change of mass of liquid species in two containers of different size;

FIG. 4 shows a first immersion heating means in a container of the delivery system shown in FIG. 1;

FIG. 5 shows a second immersion heating means in the container of the delivery system shown in FIG. 1;

FIG. 6 is a schematic representation of a second delivery system for delivering species to a processing chamber; and

FIG. 7 is a table showing states of operation of the delivery system of FIG. 6.

### DETAILED DESCRIPTION OF THE ILLUSTRATED EMBODIMENTS

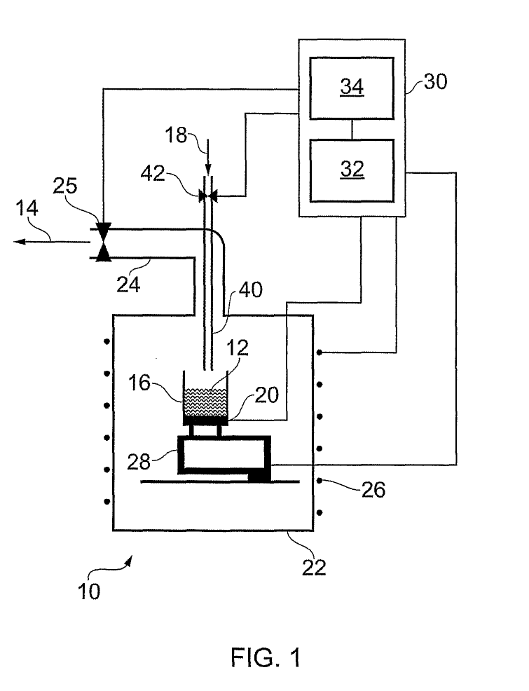

Referring to FIG. 1, a delivery system 10 is shown for delivering species 12 to a processing chamber 14. The system comprises a species container 16 for containing species supplied from a source 18 of liquid species. The container 16 may be a flask or beaker, or other vessel for containing liquid to be evaporated and is preferably open to facilitate the supply of liquid to the container and the evaporation of liquid from the container.

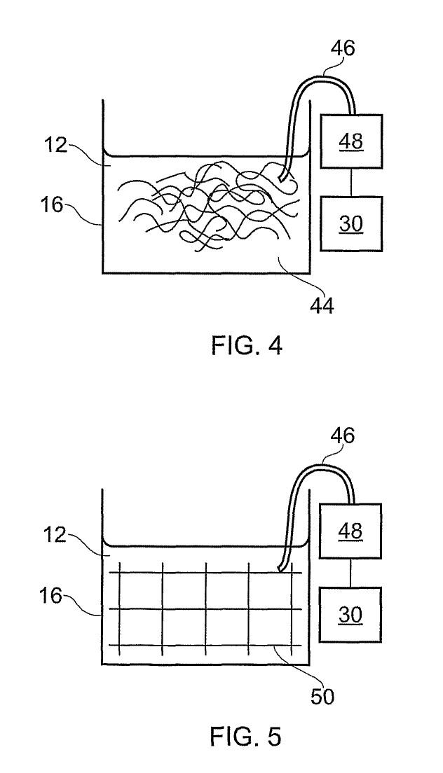

Means are provided for evaporating liquid species in container 16. The evaporating means comprise immersion heating means as described in more detail with reference to FIGS. 4 and 5. Additionally, the evaporation means may comprise a heating element 20 as shown in FIG. 1.

The heat required to achieve required evaporation is a function of a number of different factors. These factors include pressure in the surrounding region above the liquid, and the concentration of species and other constituents in the region; temperature of the liquid; inter-molecular forces in the liquid; and surface area of the liquid. Some of these other factors such as pressure can also be used to control evaporation, but changes in a rate of evaporation is more sensitive to changes in supplied heat than changes in pressure.

The inter-molecular forces in the liquid are constant for each species and the surface area is constant for a selected container of a particular size and shape. The pressure required for a given processing step is also generally constant, subject to some fluctuation. Therefore, the amount of heat provided to the liquid species in order to achieve a required flow of species into the processing chamber can be determined either by calculation or by experimentation. Such a predetermined characteristic response of the species to activation of the evaporation means can be determined for a plurality of species and for a plurality of processing steps to be conducted in the processing chamber and the evaporation means can be controlled to achieve the required rate of evaporation. More specifically, the amount of heat supplied by the evaporation means to the container in order to achieve a required evaporation rate can be predetermined.

The system 10 comprises flow guide means 22, 24 for guiding flow of evaporated species to the processing chamber 14. The flow guide means in FIG. 1 comprises an evaporation chamber 22 into which species can be evaporated from container 16 and a conduit 24 for selective fluid connection between the evaporation chamber and the processing chamber so that species can be selectively delivered from said evaporation chamber to said processing chamber. The conduit 24 comprises a valve 25 for controlling selective fluid connection between said chamber and said processing chamber. Evaporation chamber 22 and conduit 24 may comprise additional heating means 26 for reducing condensation of species which has been evaporated from the container 16 when it contacts an internal surface of the evaporation chamber and the conduit.

Monitoring means 28 measures a rate over time of evaporation of species 12 from the container 16 so that flow of evaporated species delivered to the processing chamber 14 can be monitored. The monitoring means 28 may comprise means for measuring a change in weight (or mass) of liquid species in said container over time, as shown in FIG. 1. A change in weight is a measure of the weight or mass of species which has been evaporated from container 16 and delivered to the processing chamber. Suitable weighing means includes a load cell, a balance or a strain gauge.

Alternatively or additionally, the monitoring means 28 may comprise a level sensor for sensing a level of species in the container, such as an ultrasonic, optical or capacitive sensor.

With reference to FIG. 1, a change in weight of liquid species during a delivery cycle is indicative of the flow of evaporated species delivered to the processing chamber. It can therefore be determined by measuring such a change of weight if a correct flow of evaporated species has entered the processing chamber. If a correct flow is determined to have entered the processing chamber then, it can also be determined that processing has been carried out successfully. If an incorrect flow is determined to have entered the processing chamber then, it can be determined that processing has been carried out unsuccessfully, or at least not to the standard required.

A determination of successful or unsuccessful processing can be made by a comparison between the expected change in weight for a delivery and the real time monitored change in weight. If the monitoring means 28 has a display showing weight, then such a determination can be made simply by manually comparing a monitored change of weight with a look up table.

Alternatively and as shown in FIG. 1, the predetermined characteristic rate of evaporation for one or more species for use in one or more processing steps can be stored in a memory 32 of a control means 30, and the monitoring means 28 is adapted to supply a signal relating to the monitored rate of evaporation. In this alternative, the control means 30 may comprise a comparator means 34 for comparing the monitored rate of evaporation received from the monitoring means with the predetermined characteristic rate of evaporation stored in the memory. The comparator means emits a signal based on its comparison of the monitored and predetermined rates.

In the arrangement shown in FIG. 1, the control means 30 is responsive to the signal emitted from said comparator means and can control activation of said evaporation means so that the actual rate of flow of species is adjusted to conform with said predetermined characteristic rate. A monitored change of weight may not be consistent with a predetermined rate, if pressure in the evacuation chamber is different from a pressure when the characteristic rate is determined. The pressure may vary because of operation of a vacuum pumping means, or due to other variables within the system. Such changes in pressure can be compensated for in the delivery system 10.

As shown in FIG. 1, control means 30 is operably connected to valve 25 so it can control fluid connection between said evacuation chamber 22 and said processing chamber 14 so that delivery of species from the evacuation chamber to said processing chamber can be controlled. The rate of delivery of evaporated species to the processing chamber is achieved by controlling the rate of evaporation, and valve 25 is controlled to turn the delivery “off” or “on”.

A supply conduit 40 selectively supplies liquid species to the container 16 by operation of valve 42. The control means 30 may be operably connected to valve 42 as shown in FIG. 1 so that it can control supply of liquid species to the container.

Referring to FIG. 4, immersion heating means 44 is shown for immersion in liquid species in container 16 for heating the liquid species. The immersion heating means is connected by conductors 46 to a heating control unit 48 which is operable by control means 30 to control evaporation of liquid species from container 16.

The immersion heating means 44 provides an improved arrangement for heating liquid species so that evaporation can be more accurately controlled and can more effectively supply “on-demand” the desired amount of evaporated species to the processing chamber when it is required for processing.

In addition further heating devices may include non-immersion heating arrangements in which a heating element, such as element 20, heats an exterior of the container. The container is thermally conductive and transfers heat by conduction to liquid species which is in contact with the container. The heat is subsequently distributed throughout the liquid species by convection or by way of agitation, for example using a stirrer. However, it will be appreciated that the liquid species is heated at a differential rate depending upon its proximity to the surface of the container. Some liquid species which is proximate the container surface and the surface of the liquid may achieve evaporation relatively quickly. However, other liquid species which is distal from the container surface and the liquid surface may achieve evaporation relatively slowly. It is therefore difficult to achieve a consistent and uniform flow rate of evaporated species when it is required for processing. Additionally, as it is difficult to control evaporation when it is required with such non-immersion arrangements, it may be necessary to maintain species in a warm condition so that species can be evaporated quickly when it is required. Some evaporation of the species when it is warm is inevitably and leads to waste.

The immersion heating means 44 increases (for example, as compared with prior art non-immersion arrangements) the surface area for heat transfer to the liquid species. The surface area is increased by the provision of heating formations adapted to be dispersed in the liquid species.

The formations are arranged so that the liquid species can be heated generally homogenously: that is the liquid can be heated rapidly and evaporated species can be supplied on-demand. When the liquid is heated generally homogenously, liquid in one region of the container receives an amount of heat which is generally equal to heat in another region of the container.

It is additionally desirable that the formations do not unduly restrict flow of heated liquid in order to allow heated liquid to rise to the surface of the liquid for evaporation. In FIG. 4, the heating formations are fibrous. Suitable fibrous formations may include a metallic wool, sintered matrix or other conductor with a large surface area. The container and the wool may be made from the same metal, such as steel.

Alternatively, as shown in FIG. 5, the immersion heating means 50 comprises heating formations arranged generally uniformly in a grid and immersed in the liquid species 12. The grid may take any suitable form which promotes substantially homogenous heating of the liquid species. As shown, the formations comprise a metallic cage, or lattice, having equi-spaced elements extending in orthogonal directions from nodes (in addition to the elements shown in FIG. 5, further elements extend in a direction into the page). Alternatively, the heating formations may be arranged in a honeycomb.

Agitation of the heating formations may be effected by way of a suitable agitator, displacement device or other drive means (not shown). Such agitation further enhances heat transfer as well as disrupts any layers of liquid which may act to form insulating layers around the heating formations.

A method of operation of the system of FIG. 1 will now be described.

The evacuation chamber is vented to atmospheric pressure by an aperture (not shown). The evacuation chamber 22 and container 16 are isolated from the processing chamber 14 by closing valve 25 in conduit 24. Valve 42 is opened and liquid species is supplied along conduit 40 from source 18 while the system is at atmospheric pressure. The quantity of liquid species supplied is determined by a processing step to be carried out in the processing chamber, and in this regard, a discrete quantity of liquid can be supplied for a discrete processing step or sufficient liquid can be supplied for more than one processing steps. When a required quantity of species has been supplied to container 16, valve 42 is closed and valve 25 is opened. A vacuum pumping arrangement connected to the processing chamber evacuates gas in the evacuation chamber 22 and conduit 24 to achieve a required processing pressure. Valve 25 in conduit 24 may be closed once evacuation chamber 22 has been evacuated.

The immersion heating means 44 (or 50) heats the liquid species in the container when evaporated species is required for processing. The immersion heating means can achieve rapid heating and therefore species can be supplied on-demand. Additionally or alternatively, the container 16 may be heated by heating element 20 to promote evaporation. The amount of heat energy supplied to the liquid is controlled to adjust and maintain evaporation of species from the container. When processing is required, valve 25 is opened and evaporated species is caused to flow through conduit 24 and into processing chamber 14 because of a pressure differential generated by the vacuum pumping arrangement.

During delivery of species, the evacuation chamber 22 and conduit 24 are heated by heater 26 to reduce condensation on their internal surfaces.

The monitoring means 28 transmits a signal to the comparator means 34 in accordance with a measured rate of evaporation of species from container 16. The comparator means compares the measured rate of evaporation received from the monitoring means 28 with a predetermined characteristic rate of evaporation stored in memory 32. The comparator means 34 emits a signal relating to the difference in monitored evaporation rate and the predetermined rate. The control means 30 controls the heat supplied to the liquid 12 in order to control the rate of evaporation so that actual rate of evaporation is adjusted if required to conform with the predetermined rate of evaporation.

Control means 30 is shown in FIG. 1, but in a delivery system without such control means a change in mass of species in container 16 can be monitored and if the change in mass is not as predetermined, it can be determined that an incorrect amount of species has entered the processing chamber 14 and therefore a processing step is not completed adequately.

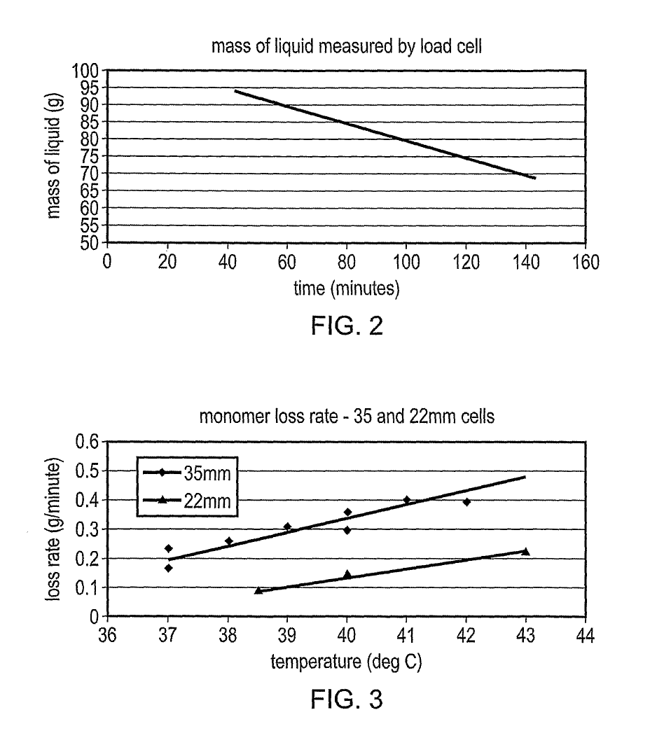

Evaporation of liquid species is monitored by measuring a change in mass over time of liquid in the container 16. FIG. 2 shows a typical graph of change in mass over time. In the example shown, the delivery of species is determined to be linear over time and the gradient of the graph is a measure of the flow of species into the processing chamber.

FIG. 3 shows a rate of loss of species over time for two selected containers with a diameter of 35 mm and 22 mm. As shown in the graph for the 35 mm container the loss rate is linear and the measured rate of delivery is as required for a processing step.

The system is suitable for delivering a monomer for use in plasma processing to a processing chamber. Such a monomer may be required from plasma deposition of a surface of an article in the processing chamber, and may be monomer for achieving a thin hydrophobic polymerised layer on an article.

In the system described with reference to FIG. 1, a carrier gas is not required to deliver species to the processing chamber and therefore vapour composition is not restricted. A mass flow controller is not required. The pressure of vapour in contact with the liquid species in container 16 is only marginally higher than that throughout the processing chamber, thus minimising the required temperature elevation of the liquid. Also, the aperture size of conduit 24 may be in the region of several centimetres reducing the propensity of the passage to blockage.

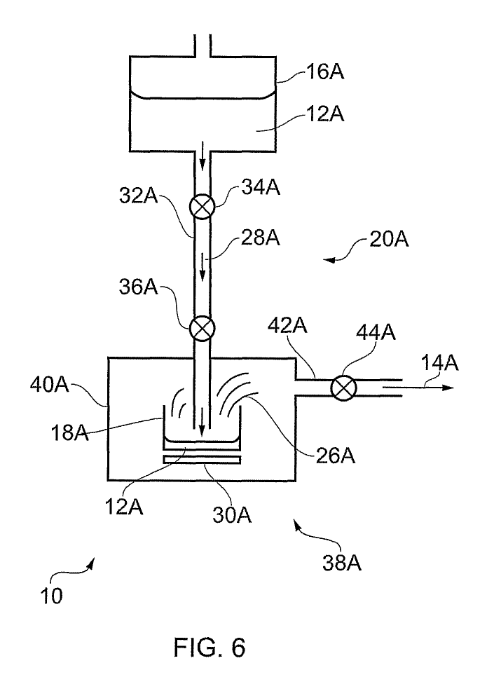

The evaporation means 44, 50 as described in FIGS. 4 and 5 can alternatively be incorporated in a species supply system as shown in FIG. 6.

Referring to FIG. 6, a delivery system 10A is shown for delivering species to a processing chamber 14A. The system 10A comprises a first container 16A which can be filled with liquid species 12A; a second container 18A for receiving liquid species from first container 16A; a first flow control means 20A for controlling a volume of liquid species which is allowed to flow from the first container to the second container; evaporation means 30A for evaporating liquid species in the second container; and a second flow control means 38A for controlling flow of evaporated species 26A from the second container to the processing chamber 14A.

The first container 16A can be filled manually by a system operator and can take the form of a hopper or a closed container with an inlet. The second container 18A may be a flask or beaker, or other vessel for containing liquid to be evaporated and is preferably open to facilitate the supply of liquid to the container and the evaporation of liquid from the container.

Evaporation means 30A is provided for evaporating the liquid species when it is in the container 18A. The liquid species in the container can be heated as shown in FIG. 6 to promote evaporation, and such heating means may comprise in addition to immersion heating element 44, 50 a heated plate or if the container is conductive, by induction of heat in the container.

The heat required to achieve required evaporation is a function of a number of different factors. These factors include pressure in the surrounding region above the liquid, and the concentration of species and other constituents in the region; temperature of the liquid; inter-molecular forces in the liquid; and surface area of the liquid. The inter-molecular forces in the liquid are constant for each species and the surface area is constant for a selected container of a particular size and shape. The pressure required for a given processing step is also generally constant, although subject to some fluctuation. Therefore, the amount of heat provided to the liquid species in order to achieve a required flow of species into the processing chamber can be determined either by calculation or by experimentation. Such a predetermined characteristic response of the species to activation of the evaporation means can be determined for a plurality of species and for a plurality of processing steps to be conducted in the processing chamber and the evaporation means can be controlled to achieve the required rate of evaporation.

The first flow control means 20A has an internal space 28A sized to receive a predetermined volume of liquid species when filled from the first container 16A. The first flow control means can control flow of liquid species into the internal space 28A and flow of liquid species from the internal space to said second container 18A.

More particularly, the first flow control means 20A comprises a conduit 32A and first valve 34A at an upstream portion of the conduit and a second valve 36A at a downstream portion of the conduit. The internal space is defined by the conduit, and the first and the second valves. The internal space 28A occupies a portion of the free space inside each of the valves in addition to the space inside the conduit, and such free space is taken into account when determining the volume of the internal space 28A.

The first valve 34A can be opened to allow liquid species to flow into the internal space 28A. The second valve 36A can be opened to allow liquid species to flow from the internal space 28A to the second container 18A. The first valve 34A can be opened and the second valve 36A can be closed to allow liquid species to fill the internal space 28A. When the internal space is filled the first valve 34A can be closed and the second valve 36A can be opened to allow a predetermined volume of liquid species, contained in the internal space 28A, to flow into the second container 18A.

The predetermined volume of liquid species can be readily changed as required by selection of any one of a plurality of conduits with different internal volumes. Different processing steps to be performed in the processing chamber 14A require different flow rates through the chamber and concentrations of evaporated species. The internal volume of conduit 32A can be selected according to a required processing step to be performed in the chamber 14A.

The second flow control means 38A as shown in FIG. 6 comprises an evaporation chamber 40A into which species can be evaporated from container 18A and a conduit 42A leading from the evaporation chamber 40A towards the processing chamber 14A. The conduit 42A comprises a valve 44A for controlling flow of evaporated species 26A from the second container 18A to the processing chamber 14A. Evaporation chamber 40A and conduit 42A may comprise additional heating means (not shown) for reducing condensation of species which has been evaporated from the container 18A when it contacts an internal surface of the evaporation chamber and the conduit.

The delivery system may form part of apparatus for plasma processing of a surface of an article. Such an apparatus typically comprises a processing chamber into which an article can be placed; a delivery system as described herein for delivering an species to the processing chamber for forming a plasma in the chamber; means for generated an electrical field internally of the processing chamber for forming a plasma when said species is supplied thereto so that a surface of said article can be processed; and pressure control means for selectively controlling pressure in the processing chamber.

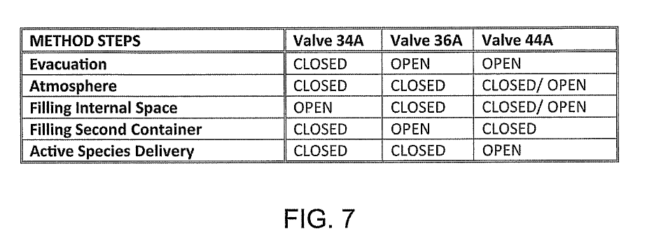

A method of operating delivery system 10A will now be described with reference to FIGS. 6 and 7. In FIG. 7, references are provided to valve 34A, valve 36A and valve 44A. References in the table to “Open” are to a valve being open to the extent that the valve is open sufficient to allow required flow of species therethrough. References to “C” are to a valve being closed to restrict or prevent the flow of species therethrough.

The first container 16A is typically filled with an amount of liquid species for delivery of species to the processing chamber sufficient for a multiplicity of processing steps.

Valve 34A is closed and valves 36A and 44A are opened. A pressure control means of a processing apparatus evacuates the processing chamber and the delivery system downstream of valve 34A to typical pressures in the region of several mTorr. Evacuation of the delivery system in this way clears blockages.

Next, valve 36A is closed and valve 44A may be either opened or closed. Valve 34A is then opened whilst valve 36A remains closed. Valve 44A may be opened or closed as it is not important in this process step. Liquid species is allowed to flow under gravity (or other means of inducing flow) from the first container 16A through valve 34A and into conduit 32A. Valve 36A which is closed restricts further flow of the species towards the second container 18A so that the internal space 28A of the first flow control means 20A can be filled.

When the internal space 28A is filled, valve 34A is closed thereby enclosing a predetermined volume of liquid species in the internal space 28A. Valve 36A is opened to allow the predetermined volume of liquid to flow into the second container 18A. Valve 44A may be opened or closed during this stage. Advantageously, valve 44A is closed to isolate the delivery system from the processing chamber so that species can be delivered to the processing chamber on command when valve 44A is opened. If valve 44A is opened during filling of the second container 18, some liquid species may evaporate and enter processing chamber 14A before it is required for processing.

When the second container 18A has received the predetermined volume of liquid, evaporation means 30A is activated to evaporate liquid species in the second container 18A. Valve 44A is closed and valve 36A may also be closed to prevent evaporated species travelling into the first flow control means 20A.

When evaporated species 26A is required for plasma processing, valve 44A is opened and vapour is drawn into the processing chamber 14A by the pressure gradient generated by the pressure control means of the plasma processing apparatus.

The volume of liquid species supplied to the second container 18A as described above is predetermined as required for a particular process step or particular process steps to be performed in the process chamber. When processing has been performed valve 36A is opened and the pressure control means evacuates the system 10A as described in the first method step above.

Such a method as described herein may suitably be controlled by control means in operative connection with valves 34A, 36A and 44A, and with evaporation means 30A. Such a control means may comprise a processor unit for controlling operation of the valves and the evacuation means, and a memory in which for instance the table shown in FIG. 7 is stored.

In addition to those features described above and shown in FIG. 6, the system 10A may suitably comprise monitoring means (not shown) for measuring a rate over time of evaporation of species from the second container 18A so that flow of evaporated species delivered to the processing chamber 14A can be monitored. The monitoring means may comprise means for measuring a change in weight (or mass) of liquid species in said container over time. A change in weight is a measure of the weight or mass of species which has been evaporated from container 18A and delivered to the processing chamber. Suitable weighing means include a load cell, balance or a strain gauge.

Alternatively or additionally, the monitoring means may comprise a level sensor for sensing a level of species in the container, such as an ultrasonic, optical or capacitive sensor.

A change in weight of liquid species during a delivery cycle is indicative of the flow of evaporated species delivered to the processing chamber. It can therefore be determined by measuring such a change of weight if a correct flow of evaporated species has entered the processing chamber. If a correct flow is determined to have entered the processing chamber then, it can also be determined that processing has been carried out successfully. If an incorrect flow is determined to have entered the processing chamber then, it can be determined that processing has been carried out unsuccessfully, or not to the standard required.

A determination of successful or unsuccessful processing can be made by a comparison between the expected change in weight for a delivery and the real time monitored change in weight. If the monitoring means has a display showing weight, then such a determination can be made simply by manually comparing a monitored change of weight with a look up table.

The invention has been described by way of two embodiments (in FIGS. 4 an 5), with modifications and alternatives, but having read and understood this description further embodiments and modifications will be apparent to those skilled in the art.

All such embodiments and modifications are intended to fall within the scope of the present invention as defined in the accompanying claims.

1. A delivery system for delivering species to a processing chamber, the system comprising: a species container for containing species supplied from a source of liquid species; heating means for heating said liquid species, said heating means being operable to control evaporation of said liquid species from said container; and flow guide means for guiding flow of evaporated species to a processing chamber, wherein said heating means includes an immersion heating means with heating formations which, in use, are adapted to be dispersed in said liquid species.

2. A delivery system as claimed in claim 1, wherein said species is a monomer for use in plasma processing.

3. A delivery system as claimed in claim 1, wherein said immersion heating means comprises heating formations adapted to be dispersed in said liquid species.

4. A delivery system as claimed in claim 3, wherein said heating formations are arranged so that said liquid species, in use, is heated generally homogenously.

5. A delivery system as claimed in claim 4, wherein said heating formations are arranged to allow generally free flow of heated liquid species in said container.

6. A delivery system as claimed in claim 3, wherein said heating formations are fibrous.

7. A delivery system as claimed in claim 6, wherein said heating formations comprise a metallic wool.

8. A delivery system as claimed in claim 3, wherein said heating formations are arranged generally uniformly in a grid for immersion in said liquid species.

9. A delivery system as claimed in claim 6, wherein said heating formations comprise a cage or lattice.

10. A delivery system as claimed in claim 1, comprises monitoring means for measuring a rate over time of evaporation of species from said container so that flow of evaporated species delivered to said processing chamber can be monitored.

11. A delivery system as claimed in claim 10, wherein said monitoring means comprises weighing means for measuring a change in weight of liquid species in said container over time.

12. A delivery system as claimed in claim 1, comprising control means configured according to a predetermined characteristic response of said species to evaporation by immersion heating means so that a rate of delivery of said species can be controlled in accordance with a required plasma process to be performed in said processing chamber.

13. A delivery system as claimed in claim 12, comprising comparator means for comparing a monitored rate of evaporation of species from said container with a predetermined characteristic rate of evaporation and emitting a signal relating to a difference between said monitored rate and said predetermined characteristic rate.

14. A delivery system as claimed in claim 13, wherein said control means is responsive to said signal emitted from said comparator means and can control activation of said evaporation means so that the monitored rate is adjusted to conform with said predetermined characteristic rate.

15. A delivery system as claimed in claim 14, wherein evaporation is controlled by activation of an external heater and/or an immersion heater.

16. A delivery system as claimed in claim 1, comprising: a supply container for filling with liquid species; a first flow control means for controlling a volume of liquid species which is allowed to flow from said first container to said second container; and a second flow control means for controlling flow of evaporated species from said second container to a processing chamber.

17. A method of delivering species to a processing chamber, the method comprising: supplying liquid species from a source of species to a container; evaporating liquid species from said container by homogenously heating said liquid species in said container; and guiding flow of evaporated species to a processing chamber.

18. A method as claimed in claim 17, wherein said species is a monomer for use in plasma processing.

19. A method as claimed in claim 17, wherein homogenous heating of said liquid active species comprises immersing heating formations in said liquid active species.

20. A method as claimed in claim 17, wherein said heating formations are fibrous.

21. A method as claimed in claim 19, wherein said heating formations are arranged generally uniformly in a grid for immersion in said liquid active species.

22. A method as claimed in claim 17, including monitoring a rate over time of evaporation of species from said container so that a metered flow of evaporated species can be delivered to said processing chamber.

23. A method as claimed in claim 22, wherein heat is supplied to said liquid species in accordance with a predetermined characteristic response of said species to supply of heat so that a rate of delivery of said species can be controlled in accordance with a required plasma process to be performed in said processing chamber.

24. A method as claimed in claim 22, wherein a monitored rate of evaporation of species from said container is compared with a predetermined characteristic rate of evaporation so that a difference between said monitored rate and said predetermined characteristic rate can be determined.

25. A method as claimed in claim 24, wherein evaporation of said species is controlled in accordance with said difference between said monitored rate and said predetermined characteristic rate and is adjusted so that said monitored rate conforms with said predetermined characteristic rate.

26. Apparatus for plasma processing of a surface of an article, the apparatus comprising: a processing chamber into which an article can be placed; a delivery system for delivering a species to the processing chamber for forming a plasma in said chamber; means for generated an electrical field internally of the processing chamber for forming a plasma when said species is supplied thereto so that a surface of said article can be processed; and pressure control means for selectively controlling pressure in the processing chamber; wherein said delivery system comprises: a species container for containing species supplied from a source of liquid species; heating means for heating said liquid species, said heating means being operable to control evaporation of said liquid species from said container; and flow guide means for guiding flow of evaporated species to the processing chamber.

27. Apparatus as claimed in claim 26, wherein said heating means is an immersion heating means.

28. (canceled)
